(19) United States
(12) Patent Application Publication
(10) Pub. No.: US 2019/0226089 A1
(43) Pub. Date: Jul. 25, 2019

(54) HIGH TEMPERATURE FACEPLATE WITH HYBRID MATERIAL DESIGN

(71) Applicant: Applied Materials, Inc., Santa Clara, CA (US)

(72) Inventors: Yuxing ZHANG, Santa Clara, CA (US); Sanjeev BALUJA, Campbell, CA (US); Kaushik ALAYAVALLI, Sunnyvale, CA (US); Kalyanjit GHOSH, San Jose, CA (US); Daniel HWUNG, Los Gatos, CA (US)

(21) Appl. No.: 16/255,377

(22) Filed: Jan. 23, 2019

Related U.S. Application Data
(60) Provisional application No. 62/621,409, filed on Jan. 24, 2018.

(51) Int. Cl. C23C 16/455; C23C 16/458

(52) U.S. Cl. CPC C23C 16/45559; C23C 16/4583

(57) ABSTRACT

Embodiments herein relate to an apparatus for use in a substrate processing chamber is disclosed herein. The apparatus has a faceplate, a support member, and a spacer. A plurality of apertures is formed through the faceplate. The faceplate is coupled to and supported by the support member. The spacer is further coupled to the support member.

### CROSS-REFERENCE TO RELATED APPLICATIONS

This application claims benefit of U.S. provisional patent application Ser. No. 62/621,409, filed Jan. 24, 2018, which is herein incorporated by reference in its entirety.

### BACKGROUND

### Field

Embodiments of the present disclosure generally relate to an apparatus for use in substrate processing chambers.

### Description of the Related Art

In the fabrication of integrated circuits, deposition processes such as chemical vapor deposition (CVD) or atomic layer deposition (ALD) are used to deposit films of various materials upon semiconductor substrates. In other operations, a layer altering process, such as etching, is used to expose a portion of a layer for further depositions. Often, these processes are used in a repetitive fashion to fabricate various layers of an electronic device, such as a semiconductor device.

Fabricating a defect free semiconductor device is desirable when assembling an integrated circuit. Contaminants or defects present on a substrate can cause operational defects within the fabricated device. For example, contaminants present in the process gas or the process gas delivery system may be deposited on the substrate, causing defects and reliability issues in the semiconductor device fabricated thereon. Accordingly, it is desirable to form a defect-free film when performing a deposition process. However, with conventional deposition devices, the layered films may be formed with defects and contaminants.

Therefore, what is needed in the art are improved apparatus for film deposition.

### SUMMARY

In one embodiment, an apparatus is provided. The apparatus has a faceplate, a support member, and a spacer. A plurality of apertures is formed through the faceplate. The faceplate is coupled to and supported by the support member. The spacer is further coupled to the support member.

In one embodiment, an apparatus is provided. The apparatus includes a faceplate, a support member, a spacer, and a sealing plate. The faceplate has a recessed distribution portion surrounded by an annular extension. The support member is formed from a ring and cylinder extending perpendicularly from the ring. The spacer is coupled to the support member at an end opposite of the face plate. The sealing plate is coupled to the spacer at an end opposite the support member.

In one embodiment, a processing chamber is provided. The processing chamber includes a body, a lid, a substrate support, a gas distribution apparatus, and a gas source. The gas distribution apparatus further includes a faceplate, a support member coupled to the faceplate, a spacer coupled to the support member, and a sealing plate coupled to the spacer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 illustrates a schematic cross-sectional view of a process chamber according to one embodiment of the disclosure.

FIG. 2 illustrates a cross-sectional view of a portion of a gas distribution apparatus according to one embodiment of the disclosure.

FIG. 3 illustrates a cross-sectional view of a portion of a gas distribution apparatus according to one embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein relate to an apparatus for use in a substrate processing chamber is disclosed herein. The gas distribution apparatus has a faceplate, a support member, and a spacer. A plurality of apertures is formed through the faceplate. The faceplate is coupled to and supported by the support member. The spacer is further coupled to the support member.

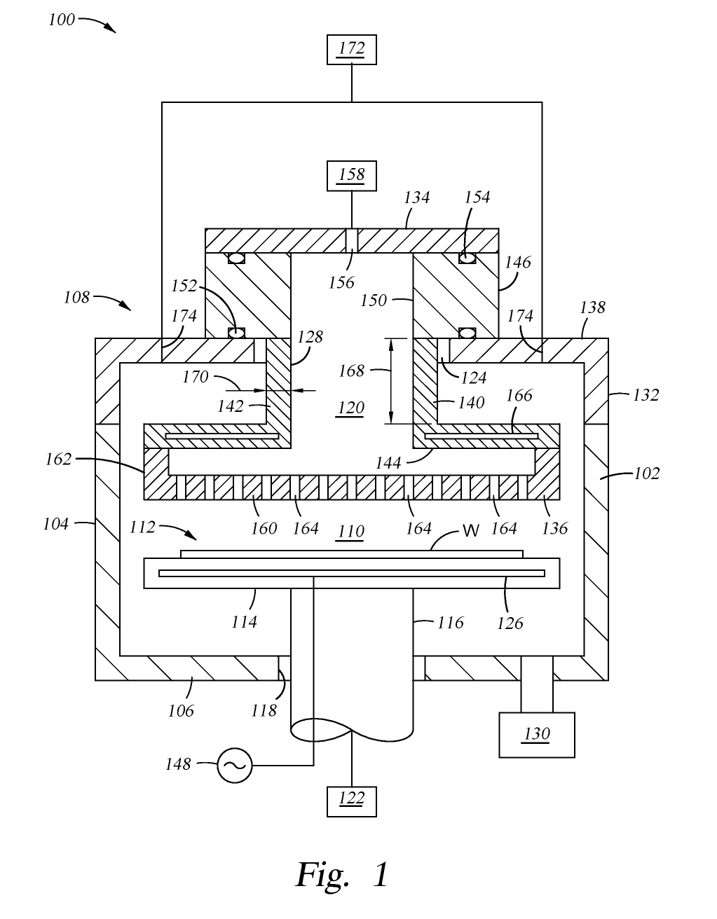

FIG. 1 illustrates a schematic cross-section of a process chamber according to one embodiment. The process chamber 100 includes a body 102 having a sidewall 104 and base 106. A lid 132 couples to the body 102 to define an interior volume therein. In one embodiment, the body 102 is formed from a metallic material, such as aluminum or stainless steel, but any material suitable for use may be utilized.

A substrate support 112 is positioned within the process chamber 100 opposite a gas distribution apparatus 108 and defines a process volume 110 therebetween. The substrate support 112 includes a support body 114 coupled to a shaft 116. The support body 112 is configured to support a substrate W thereon to facilitate processing of the substrate W. The shaft 116 is coupled to a lower surface of the support body 114 and extends out of the process chamber 100 through an opening 118 in the base 106. The shaft 116 is coupled to an actuator 122 to vertically actuate the shaft 116, and support body 114 coupled thereto, between a substrate loading position and a processing position. A vacuum system 130 is fluidly coupled to the process volume 110 in order to evacuate gases from the process volume 110.

The substrate W is disposed on the support body 114 opposite of the shaft 116. The substrate W is loaded into the process volume 110 through a port (not shown) formed in the sidewall 104. A door (not shown), such as a slit valve, is actuated to selectively enable the substrate W to pass through the port to be loaded onto or removed from the substrate support 112. An electrode 126 is optionally disposed within the support body 114 and coupled to a power source 148 through the shaft 116. The electrode 126 may be selectively biased by the power source 148 to create an electromagnetic field to chuck the substrate W to the support body 114. In certain embodiments, a heater (not shown), such as a resistive heater, is disposed within the support body 114 to heat the substrate W disposed thereon to a desired a temperature to facilitate processing.

The gas distribution apparatus 108 includes a sealing plate 134, a support member 140, and a faceplate 136. The faceplate 136 includes a recessed circular distribution portion 160 surrounded by an annular extension 162 that extends perpendicularly from the faceplate 136. In one embodiment, the faceplate 136 is formed from a metal, such as aluminum or stainless steel. In one embodiment, the faceplate 136 has a circular body but other shapes, such as square or ovoid, are contemplated.

The support member 140 is coupled to the faceplate 136 at the annular extension 162. The support member 140 is formed from a ring 144 and cylinder 142 extending perpendicularly from the ring 144. The support member 140 is coupled to and supported by a spacer 146 that extends into the process chamber 100 toward the process volume 110. The ring 144 of the support member 140 is coupled to the faceplate 136 to support the faceplate 136 adjacent the process volume 110 and opposite the substrate support 112. The cylinder 142 of the support member 140 extends from the ring 144, through the port 124, and couples to the spacer 146. In one embodiment, the support member 140 is formed from a ceramic material, such as alumina or aluminum nitride. An aperture 128 is formed axially through the cylinder 142 of the support member 140 to permit fluid flow therethrough. In one embodiment, the aperture 128 has a circular cross-section but other shapes, such as ovoid, are contemplated. Further, while the ring 144 and the cylinder 142 have circular shapes in certain embodiments, other shapes such as square or ovoid, may be practiced herewith.

In one embodiment, the spacer 146 is formed in a circular configuration and has an aperture 150 formed axially therethrough. In certain embodiments, the aperture 150 in the spacer 146 has an inside diameter that is equal to an inside diameter of the aperture 128 in the cylinder 142 of the support member 140. The spacer 146 has an outer diameter that is greater than an inner diameter of the port 124 to facilitate support of the spacer 146 on the lid 132. The spacer 146, the lid 132, and the support member 140 are sized to enable for thermal expansion of the cylinder 142 during processing within the process chamber 100, or to enable for differences in thermal expansion between the cylinder 142 and the lid 132. A seal 152 is disposed between the spacer 146 and an upper surface 138 the lid 132. The seal 152 prevents leakage of a fluid, such as a process gas, between the spacer 146 and the lid 132 through the gap. Therefore, a reduced pressure environment may be maintained within the process volume 110. In one embodiment, the seal 152 is an O-ring formed from a material such as polytetrafluoroethylene (PTFE), rubber, or silicone. Other seal designs, such as sheet gaskets or bonds, are also contemplated.

In one embodiment, the spacer 146 is formed from a metal. Exemplary materials include aluminum and stainless steel. In one embodiment, the spacer 146 is coupled to the cylinder 142 of the support member 140 by fasteners (not shown), such as threaded fasteners. In another embodiment, the spacer 146 is coupled to the support member 140 by bonding, such as brazing or welding, or an adhesive compound.

The gas distribution apparatus 108 further includes a sealing plate 134 disposed at and coupled to the spacer 146, opposite the support member 140. In one embodiment, the sealing plate 134 has circular shape but other shapes, such as ovoid or square, may be utilized. A gas port 156 is formed through the sealing plate 134 to facilitate flow of a gas, such as a processing gas or a cleaning gas, from a gas source 158 through the gas port 156 and into the process volume 110. In one embodiment, the gas source 158 is a plurality of gas sources, each providing a gas to the gas port 156. A seal 154 is disposed between the spacer 146 and the sealing plate 134 to prevent leakage of a fluid, such as the gas provided by the gas source 158, therebetween.

The apertures 128, 150, in conjunction with the distribution portion 160 of the faceplate 136, define a gas flow volume 120. The gas provided by the gas source 158 flows through the gas port 156 into the gas flow volume 120. A plurality of apertures 164 are formed through the faceplate 136 in the distribution portion 160. The apertures 164 enable fluid communication between the gas flow volume 120 and the process volume 110. The gas flows from the gas flow volume 120 into the process volume 110 through the apertures 164 to facilitate processing of the substrate W.

The support member 140 includes one or more heaters 166 disposed in the ring 144. The heaters 166 may be any mechanism capable of providing heat to the faceplate 136. In some embodiments, the heaters 166 include a resistive heater that is embedded within and encircles the ring 144. In other embodiments, the heaters 166 include a channel (not shown) that flows a heated fluid therethrough.

The heaters 166 heat the support member 140, which conducts the heat to the faceplate 136 to heat the faceplate 136 to a predetermined temperature, for example, 300 F, 400 F, 500 F, or even higher. The increase in temperature of the faceplate 136 during processing, such as a chemical vapor deposition process, results in significantly less contaminant particle deposition on the substrate W. The faceplate 136 is formed from a thermally conductive material, such as a metal, which may be, for example, aluminum, thus enabling the faceplate 136 to be heated to the temperature described above. Therefore, the temperature of the faceplate 136 can be efficiently raised to the elevated temperatures to minimize deposition of contaminant particles on the substrate W during processing. Meanwhile, the support member 140 is formed from a thermally insulating material, such as a ceramic, in order to reduce heat transfer from the heaters 166 to a portion thereof away from the faceplate 136. The design of the support member 140 and the faceplate 136, such as materials thereof and location of the heaters, is selected to efficiently transfer heat therebetween to heat the faceplate 136 while minimizing heat transfer therefrom.

A cross-section of the cylinder 142 has a length 168 and a width 170. The length 168 and the width 170 are selected so that the cross-section has a large aspect ratio (e.g. ratio of length to width). In some embodiments, the length 168 is, for example, between about 18 inches and 22 inches. In some embodiments, the width 170 is, for example, between about 40 mils and about 200 mils. The aspect ratio may be between about 90 and about 550, for example 110 to 300, such as 130. The cross-section having a large aspect ratio minimizes the conductance area for heat to be transferred from the heater 166, thus minimizing heat conducted through the cylinder 142 to the spacer 146 and the seal 152.

In conventional designs, a faceplate is generally not heated to the high temperatures described herein because the sealing materials degrade at elevated temperatures, such as 250 F and above. However, by utilizing the high aspect ratio of the cylinder 142 as described herein, the faceplate 136 in the processing region may be heated to elevated temperatures while the spacer 146 and the seal 152 disposed at an end opposite of the cylinder 142 from the faceplate 136 are maintained at a lower temperature. Thus, contaminant particle disposition on the substrate W during processing is limited while the seals 152 are protected from degradation. Therefore, a seal is maintained around the processing volume while the faceplate 136 is heated to high temperatures.

A purge gas source 172 is coupled to the process volume 110 through a plurality of purge ports 174. The purge ports 174 flow a gas, such as an inert gas, from the purge gas source 172 into the process volume 110. The purge facilitates removal of process gases from the process chamber 100.

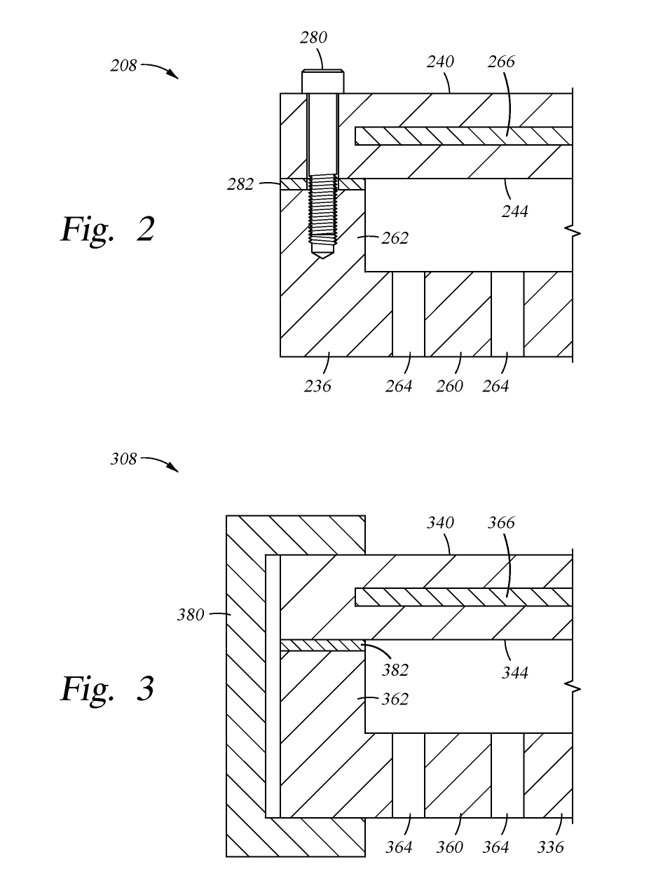

FIG. 2 illustrates an enlarged cross-section view of a portion of a distribution apparatus 208. The distribution apparatus 208 may be utilized in place of the distribution apparatus 108 of FIG. 1. FIG. 2 illustrates one example of coupling a faceplate 236 to a ring 244 of a support member 240. The faceplate 236 has a distribution portion 260 surrounded by an annular extension 262. Apertures 264 are formed through the distribution portion 260. A heater 266 is disposed within the ring 244.

A threaded fastener 280 couples the support member 240 to the faceplate 236 at the annular extension 262. A conduction layer 282 is optionally disposed between the annular extension 262 and the ring 244. The conduction layer 282 is configured to improve heat transfer between the ring 244 having the heater 266 disposed therein and the faceplate 236. In one embodiment, conduction layer 282 is a thermally conductive bonding layer. In another embodiment, the conduction layer 282 is a high conductance foil, such as gold or nickel.

FIG. 3 illustrates an enlarged peripheral region of a portion of a gas distribution apparatus 308. The gas distribution apparatus 308 is like the gas distribution apparatus 208 but utilizes a different coupling mechanism. Similar to gas distribution apparatus 208, the faceplate 336 has a distribution portion 360 surrounded by an annular extension 362. Apertures 364 are formed through the distribution portion 360. In FIG. 3, a clamp 380 couples the faceplate 336 to the support member 340. In one example, the clamp 380 is an annular member which surrounds the faceplate 336 and the support member 340. In another example, the clamp 380 is a plurality of arcuate members. The clamp 380 delivers a compressive force between the ring 344 and the annular extension 362, thereby coupling the faceplate 336 and the support member 340. A conduction layer 382 is optionally disposed between the annular extension 362 and the ring 344. The conduction layer 382 is configured to improve heat transfer between the ring 344 having the heater 366 disposed therein and the faceplate 236. In one embodiment, conduction layer 382 is a thermally conductive bonding layer. In another embodiment, the conduction layer 382 is a high conductance foil, such as gold or nickel.

The embodiments described herein advantageously reduce the deposition of contaminant particles on a substrate by enabling a faceplate to be heated to a relatively higher temperature while maintaining chamber sealing. The high aspect ratio of the support member of the gas distribution apparatus operates as a thermal choke that enables the temperature of the faceplate to be increased to a high temperature, limiting the deposition of contaminant particles while mitigating heat transfer to temperature-sensitive seals.

While the foregoing is directed to embodiments of the present disclosure, other and further embodiments of the disclosure may be devised without departing from the basic scope thereof, and the scope thereof is determined by the claims that follow.

What is claimed is:

1. An apparatus for a processing chamber, comprising:
a faceplate, the faceplate comprising:
a distribution portion;
a plurality of apertures formed through the distribution portion; and
an annular extension surrounding the distribution portion;
a support member coupled to the faceplate, the support member comprising:
a ring; and
a cylinder coupled to the ring; and
a spacer coupled to the support member at an end thereof opposite of the faceplate.

2. The apparatus of claim 1, wherein an aspect ratio of the cylinder is between 90 and 550.

3. The apparatus of claim 1, further comprising a heater disposed in the support member.

4. The apparatus of claim 1, further comprises a seal disposed on the spacer.

5. The apparatus of claim 4, further comprising a heater disposed in the ring.

6. The apparatus of claim 5, wherein an aspect ratio of the cylinder is between 90 and 550.

7. The apparatus of claim 1, wherein an aperture is formed through the spacer and the support member.

8. The apparatus of claim 7, further comprising a gas source coupled to the aperture.

9. The apparatus of claim 1, wherein the faceplate is coupled to the support member by threaded fasteners.

10. The apparatus of claim 1, wherein the faceplate is coupled to the support member by clamps.

11. The apparatus of claim 1, further comprising a conductive layer disposed between the faceplate and the support member.

12. The apparatus of claim 1, wherein the support member is formed from alumina or aluminum nitride.

13. The apparatus of claim 1, wherein the faceplate is formed from aluminum.

14. A gas distribution apparatus, comprising:
a faceplate having a recessed distribution portion surrounded by an annular extension;
a support member coupled to the faceplate, the support member formed from a ring and a cylinder extending perpendicularly from the ring;
a spacer coupled to the support member at an end thereof opposite of the faceplate; and
a sealing plate coupled to the spacer at an end thereof opposite of the support member.

15. The apparatus of claim 14, wherein the faceplate is coupled to the ring at the annular extension.

16. The apparatus of claim 15, wherein a conduction layer is disposed between the annular extension and the ring.

17. The apparatus of claim 16, wherein the conduction layer is a high conductance foil.

18. The apparatus of claim 15, wherein a resistive heater is disposed in the ring.

19. The apparatus of claim 14, wherein the cylinder has an aspect ratio of about 110 to about 300.

20. A processing chamber, comprising:
a body having a sidewall and a base;
a lid coupled to the body and defining an interior volume therein;
a substrate support extending through the base and into the interior volume, the substrate support having a shaft coupled to a support body;
a gas distribution apparatus coupled to the lid and extending into the interior volume, the gas distribution apparatus comprising:
a faceplate, the faceplate having a recessed distribution portion surrounded by an annular extension and a plurality of apertures formed through the recessed distribution portion;
a support member coupled to the faceplate, the support member formed from a ring and a cylinder extending perpendicularly from the ring;
a spacer coupled to the support member at an end thereof opposite of the faceplate; and
a sealing plate coupled to the spacer at an end thereof opposite of the support member; and
a gas source coupled to the gas distribution apparatus.
